(19) United States
(12) Patent Application Publication
(10) Pub. No.: US 2008/0106171 A1
(43) Pub. Date: May 8, 2008

(54) Self-focusing acoustic transducers to cool mobile devices

(76) Inventor: Rajiv K. Mongia, Portland, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/265,791

(22) Filed: Sep. 30, 2005

(51) Int. Cl. H01L 41/00; H02N 2/00

(52) U.S. Cl. 310/334

(57) ABSTRACT

A self-focusing acoustic transducer for cooling a computing device is described. The self-focusing acoustic transducer is integrated into a heat generating component or into an external wall of a mobile computing device. The self-focusing acoustic transducer may be part of an array. A method of fabricating a self-focusing acoustic transducer as an integrated part of a heat generating component or as part of an external wall of a mobile computing device is also described, as well as a method of cooling a computing device using self-focusing acoustic transducers.

### BACKGROUND

1. Field

The field of invention relates generally to heat management and more particularly to heat management using self-focusing acoustic transducers to cool mobile devices.

2. Discussion of Related Art

Heat management can be critical in many applications. Excessive heat can cause damage to or degrade the performance of mechanical, chemical, electric, and other types of devices. Heat management becomes more critical as technology advances and newer devices continue to become smaller and more complex, and as a result run at higher power levels and/or power densities.

Modern electronic circuits, because of their high density and small size, often generate a substantial amount of heat. Complex integrated circuits (ICs), especially microprocessors, generate so much heat that they are often unable to operate without some sort of cooling system. Further, even if an IC is able to operate, excess heat can degrade an IC's performance and can adversely affect its reliability over time. Inadequate cooling can cause problems in central processing units (CPUs) used in personal computers (PCs), which can result in system crashes, lockups, surprise reboots, and other errors. The risk of such problems can become especially acute in the tight confines found inside mobile computers and other portable computing and electronic devices.

Prior methods for dealing with such cooling problems have included using heat sinks, fans, and combinations of heat sinks and fans attached to ICs and other circuitry in order to cool them. However, in many applications, including portable and handheld computers, computers with powerful processors, and other devices that are small or have limited space, these methods may provide inadequate cooling.

Conventional synthetic jet actuators require an acoustic chamber in order to work appropriately. This makes the entire synthetic jet relatively large and difficult to implement within the tight confines of a mobile device such as a notebook computer. Additionally, because of the large size, the distance between the actuator of the convention synthetic jet actuators and the hotspots is significantly large for portable devices because the synthetic jets are incorporated as non-integrated parts that flow air across the hot spots and not directly away from the hot spots.

### BRIEF DESCRIPTION OF THE DRAWINGS

FIG. 1A illustrates a cross-sectional view of an embodiment of a self-focusing acoustic transducer.

FIG. 1B illustrates a top view of a ring electrode according to one embodiment.

FIG. 1C illustrates a three-dimensional top view of one embodiment of a self-focusing acoustic transducer.

FIGS. 2A-2L illustrate an embodiment of a method of fabrication of an integrate self-focusing acoustic transducer.

FIG. 3 illustrates an array of self-focusing acoustic transducers formed on the backside of a heat generating component according to one embodiment.

### DETAILED DESCRIPTION

A method and apparatus to use a self-focusing acoustic transducer (SFAT) for cooling in a mobile computing device is described. In the following description, numerous specific details are set forth. However, it is understood that embodiments may be practiced without these specific details. In other instances, well-known circuits, structures and techniques have not been shown in detail in order not to obscure the understanding of this description.

Reference throughout this specification to “one embodiment” or “an embodiment” indicate that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

A self-focusing acoustic transducer (SFAT) for cooling a computing device is described. A self-focusing acoustic transducer is integrated into a heat generating component or into an external wall of a mobile computing device. The term heat generating component as used herein is an electrical component capable of generating heat when operated. The self-focusing acoustic transducer may be part of an array that is integrated into the heat generating component to remove heat from hot spots. A method of fabricating a self-focusing acoustic transducer as an integrated part of a heat generating component is also described, as well as a method of cooling a computing device using self-focusing acoustic transducers.

When used within a device for cooling purposes the self-focusing acoustic transducer can pump fluid away from hot areas to cool a computing device. The fluid can be a gas or a liquid. The gas may be air or any other gas known to one of ordinary skill in the art. The liquid may be water or any other liquid known to one of ordinary skill in the art. The different configurations needed to implement an SFAT within a device for cooling purposes when the fluid is a liquid instead of a gas would be known to one of ordinary skill in the art. Heat generating components of a mobile computing device, such as an integrated circuit of a memory, a chipset, or a processor may be cooled with an SFAT. In one particular embodiment an SFAT may be used to cool down hot spots of a heat generating component. A hot spot is defined as a region of the heat generating device that has a temperature greater than the average temperature of the surface of the heat generating device. In one particular embodiment, the hot spot may have a temperature that is approximately 5 degrees to 20 degrees greater than the surrounding surface area of the heat generating component. An SFAT or an array of SFAT's may also be formed on a heat spreader to further dissipate heat from the heat spreader. Additionally, the pumping away of hot air to cooler areas can cause the overall cooling of the device by convection, or bulk air flow. The SFAT focuses acoustic waves through a constructive interference without any acoustic lens. The SFAT also does not create any heat during operation and therefore is a valuable cooling mechanism for a device such as a laptop computer.

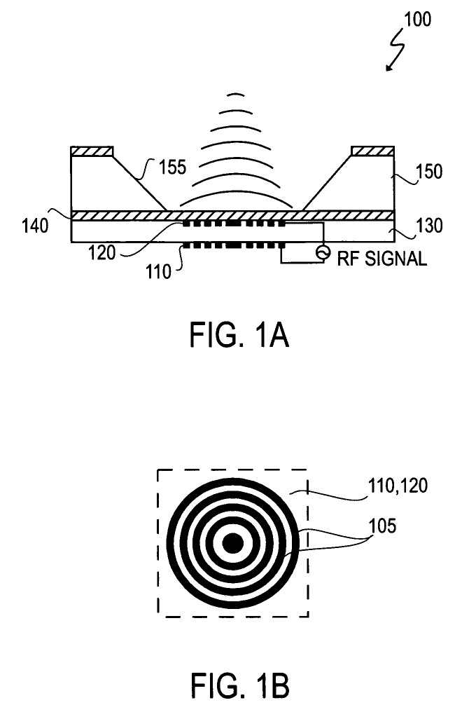

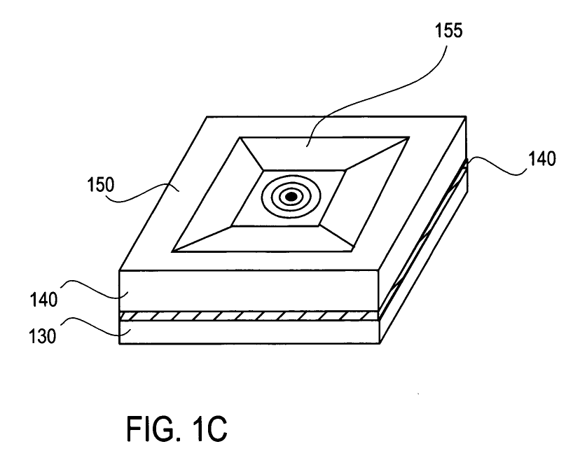

FIG. 1a illustrates a cross-sectional view of a self-focusing acoustic transducer (SFAT) 100. The SFAT 100 is formed of a pair of electrodes, a first electrode 110 and a second electrode 120, formed on either side of a layer of piezoelectric material 130. In an embodiment, the piezoelectric layer may be formed of a piezoelectric material such as zinc oxide (ZnO). Alternate piezoelectric materials that may be used include minerals such as quartz (SiO₂) and barium titanate (BaTiO₃). Alternatively, polymer materials may be used such as polyvinylidene fluoride (PVFD) (—CH₂-CF₂—)ₙ. Polymer materials such as PVFD may be valuable because they exhibit piezoelectricity several times larger than quartz. The thickness of the piezoelectric layer 130 may be in the approximate range of 0.5 micrometers (μm) and 50 um and more particularly in the range of 3 μm to 10 μm. The thickness of the ZnO film may vary depending on the operating frequency desired for the SFAT. The thinner the ZnO film, the higher the operating frequency. The operating frequency of the ZnO film may be in the approximate range of 100 Hz (Hertz) and 10 kHz (kilohertz). When an electrical field is applied to the piezoelectric layer 130, the piezoelectric layer 130 is mechanically distorted, causing movement.

The pair of electrodes may be formed of a metal such as aluminum. As illustrated in FIG. 1b, each of the electrodes is formed of a series of complete annular electrode rings 105. The rings are progressively larger and are formed around one another to form half-wave band sources. The ring-shaped electrodes 110 and 120 are designed to give a large focused acoustic pressure directed perpendicular to the plane of the annular rings 105 of the electrodes. The diameter of the ring shaped electrodes may be in the approximate range of 50 μm and 5000 μm, and more particularly in the range of 250 μm and 750 μm. The diameter of the ring shaped electrodes may be selected based on the size of the fluid wave to be produced by the SFAT.

When the SFAT is excited with a burst of radio frequency (rf) signal, it generates acoustic waves that propagate in the fluid away from the annular electrode rings 105 in a direction perpendicular to the annular electrode rings 105. If the electrodes 110, 120 of the SFAT are properly designed, the acoustic waves will add in-phase at the focal point. The lensless design borrows its concept from an optical Fresnel lens, which blocks certain areas of light to obtain intensity enhancement. Similarly, only certain areas of the piezoelectric layer 130 generate acoustic waves that arrive at a focal point in phase. The other areas that would have generated waves with a phase difference of pi at the focal point are designed not to generate any acoustic waves. This is what is called by some a Fresnel Half-Wave-Band (FHWB) source. Additional discussion of this concept can be found at the URL http://mems.usc.edu/sfat.htm last visited on Aug. 22, 2005. The acoustic waves generated by the successive annular rings 105 are designed to arrive at the focal point with finite delays equal to a multiple of the wavelength.

A membrane 140 is formed above the second electrode 120 and the piezoelectric layer 130. This membrane is formed of a low-stress material that can withstand the forces exerted on it by the mechanical distortion of the piezoelectrical layer 130. In one embodiment the membrane 140 is silicon nitride (SiₓN_{y}) Other low stress materials known to those of ordinary skill in the art may also be used. The piezoelectric layer 130 in combination with the first electrode 110 and the second electrode 120 and the membrane 140 form the actuator of the SFAT. The chamber of the SFAT is formed by a well that has been etched into a chamber material 150 such as silicon. The walls 155 of the chamber are formed at an angle or are curved to help focus the wave of fluid that is formed by the SFAT when an electrical pulse is applied to the pair of electrodes, the first electrode 110 and the second electrode 120. The angle of the walls 155 of the SFAT may be in the approximate range of 30 degrees and 60 degrees. In an embodiment, the walls 155 may be formed at a 45 degree angle. The angle may be selected based on the amount of focusing needed. FIG 1c illustrates a three-dimensional top view of an SFAT 100 to provide further perspective.

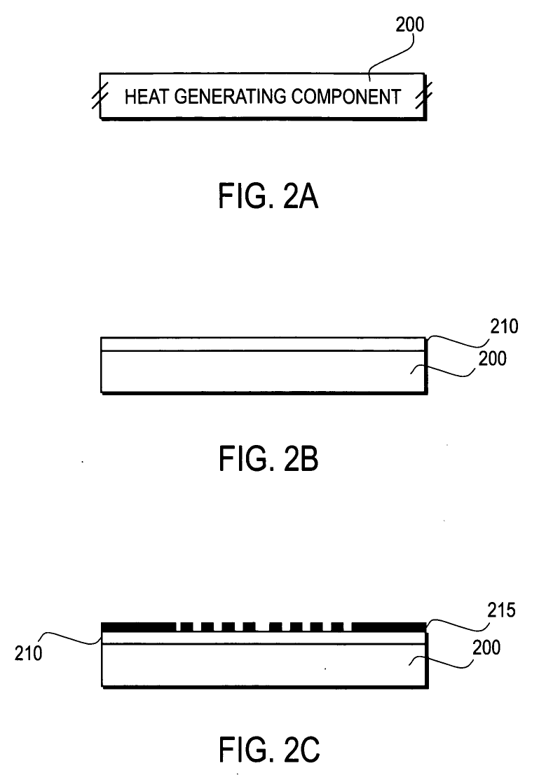

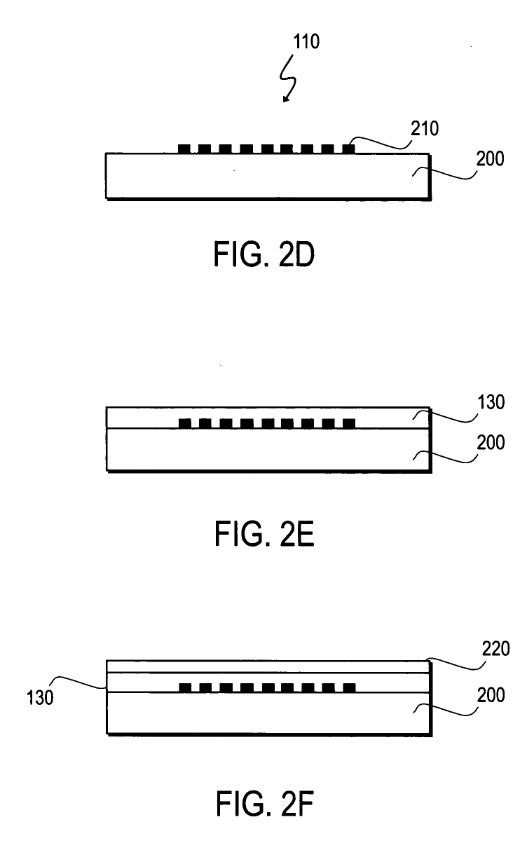

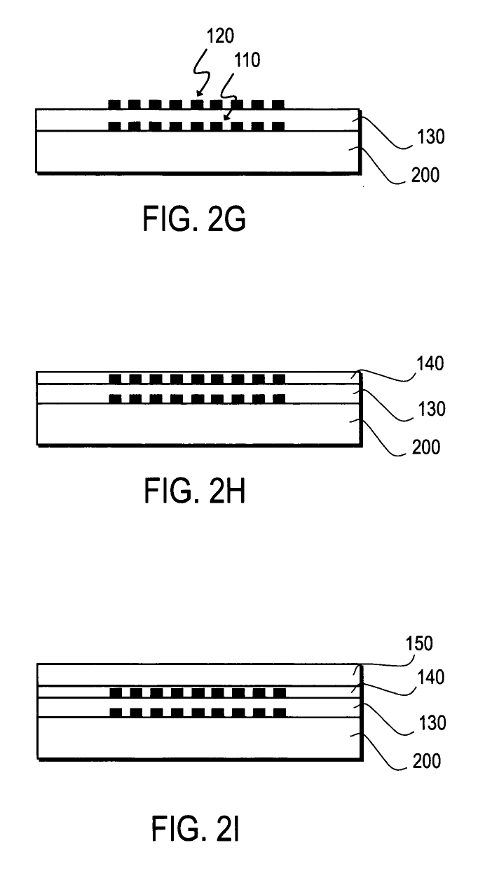

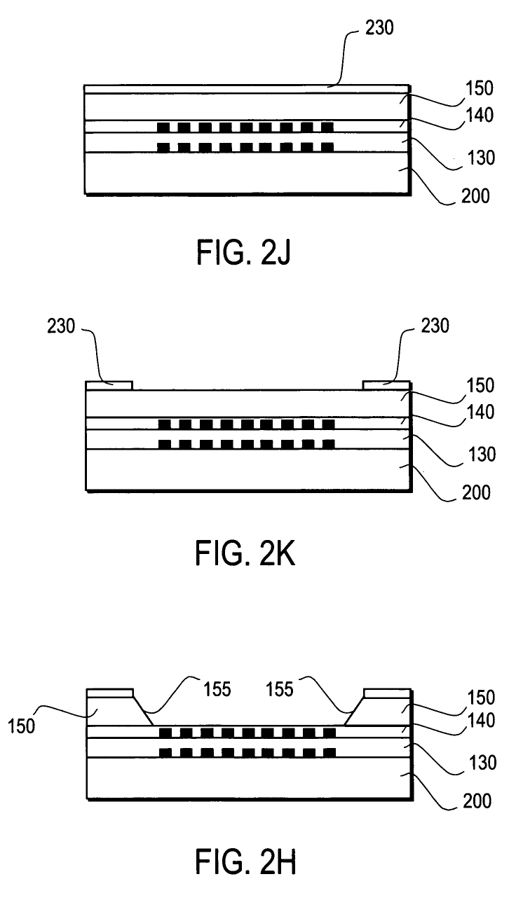

In one embodiment, the self-focusing transducers may be fabricated to be integrated into a heat generating component. FIGS. 2a-2l illustrate an embodiment of a fabrication process to form an SFAT within a heat generating component 200. FIG. 2a illustrates a heat generating component 200. The heat generating component may be a processor, a chipset, a graphic controller, or any alternative device that generates heat. In one embodiment, the heat generating component may be a heat spreader that is coupled to a package containing a device such as a processor or a chipset.

In FIG. 2b a first metal layer 210 is deposited on to the heat generating component to form a first electrode 110. The first metal layer 210 may be deposited by the evaporation of the metal onto the heat generating unit. The first metal of the metal layer 210 may be aluminum or another conductive metal such as copper or silver. In FIG. 2c the first metal layer 210 is masked with a mask 215 to form the pattern of the first electrode 110. At FIG. 2d the first metal layer 210 is patterned to form the first electrode 110 having a series of annular rings within one another as illustrated in FIG. 1b.

In FIG. 2e a piezoelectric layer 130 is deposited over the first electrode 110. In one embodiment the piezoelectric material may be zinc oxide (ZnO). The thickness of the piezoelectric layer 130 may be in the approximate range of 0.5 μm and 50 μm and more particularly in the range of 3 μm to 10 μm. The thickness of the ZnO film may vary depending on the operating frequency desired for the SFAT. The thinner the ZnO film, the higher the operating frequency. The operating frequency of the ZnO film may be in the approximate range of 100 Hz-10 kHz.

In FIG. 2g the second electrode 120 is formed by the same method as described above for the first electrode 110. A second metal layer 220 is deposited, masked and patterned to form the second electrode 120. The same metal that was used for the first electrode 110 may be used to form the second electrode 120. The second electrode 120 is formed directly over the first electrode 110 and is identical to the first electrode 110. Each of the electrodes may be formed to have a diameter of approximately 500 um. The number of rings within each of the electrodes may be determined by space limitations and by the desired focal point of the fluid wave to be created .

A thin film of a low stress material is then deposited at FIG. 2h to form the membrane 140. In one embodiment the low stress material is silicon nitride. The membrane 140 is formed over the second electrode 120 and the piezoelectric material 130 to a thickness in the approximate range of 0.005 micrometers (μm) and 5 um and more particularly in the range of 0.5 μm and 0.8 μm.

At FIG. 2i a chamber material 150 is deposited. In one embodiment the chamber material 150 is silicon. At FIG. 2j a hard mask material 230 is deposited over the chamber material 150. In one embodiment the hard mask material 230 is silicon nitride. The hard mask material 230 is then patterned to form a mask for the patterning of the chamber material 150 as illustrated in FIG. 2k. The chamber material 150 is then etched to form a well within the chamber material above the first electrode and the second electrode. The well is etched down to the membrane 140 that acts as an etch stop. In one embodiment the walls may be etched to form angled walls 155 within the well. For example, in an embodiment where the chamber material is silicon, the silicon is etched anisotropically with an etchant such as potassium hydroxide (KOH) to form the angled walls such as those illustrated in FIG. 2l. The dimensions at the bottom of the well are formed to be slightly larger than the dimensions of the electrodes 110 and 120. In one embodiment, where the diameter of the electrodes is 500 um the dimensions at the bottom of the well may be formed to a size of 1.5 mm×1.5 mm. A three-dimensional top view of the SFAT formed by an embodiment of this process is illustrated in FIG. 1c.

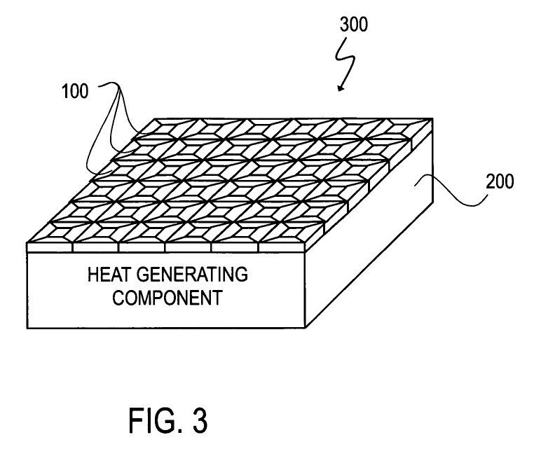

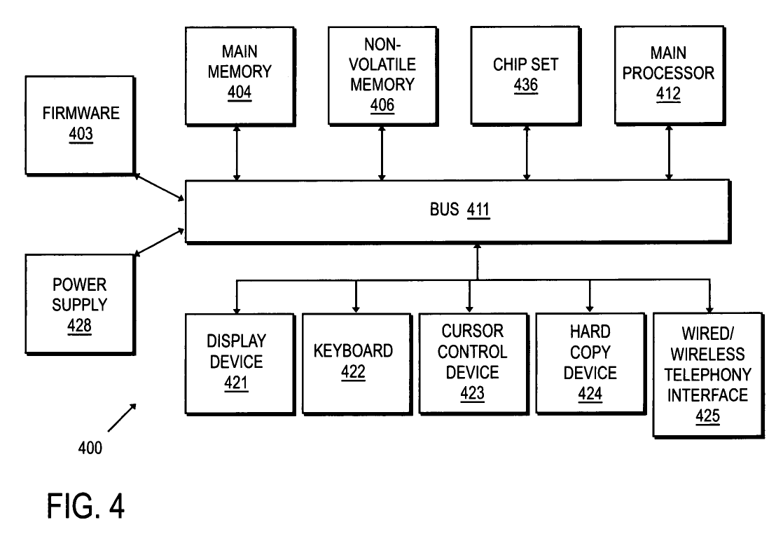

The SFAT may be formed as part of an array 300 of SFATs as illustrated in FIG. 3. The array 300 may be formed on the backside of a heat generating component 200 of a device or alternatively on the inside surface of an external wall of a computing device. In one particular embodiment the array 300 is formed on the backside of a heat generating component of a mobile device or on an external wall of a mobile computing device. The heat generating component may be a processor, a chipset, or a heat spreader. In one embodiment the array 300 substantially covers the backside of the heat generating component 200. In an alternate embodiment the array 300 is formed over the hot-spots of the heat generating component 200. The number of SFATs within the array 300 may vary depending on the dimensions of the heat generating unit 200 and depending on the number of hot spots in the embodiment where the array is formed over the hot spots.

An SFAT may be used to cool a mobile computing device. In this embodiment, an SFAT that is integrated into a heat generating component of the mobile computing device is used to cool the mobile computing device by generating pulses of fluid waves to remove the heat from the surface of the heat generating component. The pulses of fluid are created by pulsing the pair of electrodes of the SFAT with a radio-frequency signal to create an acoustic wave within the well of the SFAT to push fluid away from the heat generating component. The radio-frequency signal may be pulsed in the approximate range of 100 Hz-10 kHz to the pair of electrodes of the SFAT approximately every 10 milliseconds (ms) to every 100 microseconds (ps). In one embodiment the pulsing of the pair of electrodes may be started once the heat generating component has reached a temperature above a pre-determined threshold temperature and the pulsing of the pair of electrodes may be stopped once the heat generating component has reached a temperature below the pre-determined threshold temperature.

In one embodiment, the hot air may be removed from the surface of the heat generating component by convection caused by the flow of the hot air away from the surface and the resultant influx of air to the surface. In one embodiment a fan or an air jet may be positioned to flow the hot air away from the heat generating component once the SFAT array has pushed the hot air from the surface of the heat generating component.

FIG. 4 illustrates a block diagram of an example computer system that may use an embodiment of the self-focusing acoustic transducer to cool the computer system. In one embodiment, computer system 400 comprises a communication mechanism or bus 411 for communicating information, and an integrated circuit component such as a processor 412 coupled with bus 411 for processing information. One or more of the components or devices in the computer system 400 such as the processor 412 or a chip set 436 may be cooled by an embodiment of the self-focusing acoustic transducer.

Computer system 400 further comprises a random access memory (RAM) or other dynamic storage device 404 (referred to as main memory) coupled to bus 411 for storing information and instructions to be executed by processor 412. Main memory 404 also may be used for storing temporary variables or other intermediate information during execution of instructions by processor 412.

Firmware 403 may be a combination of software and hardware, such as Electronically Programmable Read-Only Memory (EPROM) that has the operations for the routine recorded on the EPROM. The firmware 403 may embed foundation code, basic input/output system code (BIOS), or other similar code. The firmware 403 may make it possible for the computer system 400 to boot itself.

Computer system 400 also comprises a read-only memory (ROM) and/or other static storage device 406 coupled to bus 411 for storing static information and instructions for processor 412. The static storage device 406 may store OS level and application level software.

Computer system 400 may further be coupled to a display device 421, such as a cathode ray tube (CRT) or liquid crystal display (LCD), coupled to bus 411 for displaying information to a computer user. A chipset, such as chipset 436, may interface with the display device 421.

An alphanumeric input device (keyboard) 422, including alphanumeric and other keys, may also be coupled to bus 411 for communicating information and command selections to processor 412. An additional user input device is cursor control device 423, such as a mouse, trackball, trackpad, stylus, or cursor direction keys, coupled to bus 411 for communicating direction information and command selections to processor 412, and for controlling cursor movement on a display device 412. A chipset, such as chipset 436, may interface with the input output devices.

Another device that may be coupled to bus 411 is a hard copy device 424, which may be used for printing instructions, data, or other information on a medium such as paper, film, or similar types of media. Furthermore, a sound recording and playback device, such as a speaker and/or microphone (not shown) may optionally be coupled to bus 411 for audio interfacing with computer system 400. Another device that may be coupled to bus 411 is a wired/wireless communication capability 425.

Computer system 400 has a power supply 428 such as a battery, AC power plug connection and rectifier, etc.

In one embodiment, the software used to facilitate the routine can be embedded onto a machine-readable medium. A machine-readable medium includes any mechanism that provides (i.e., stores and/or transmits) information in a form accessible by a machine (e.g., a computer, network device, personal digital assistant, manufacturing tool, any device with a set of one or more processors, etc.). For example, a machine-readable medium includes recordable/non-recordable media (e.g., read only memory (ROM) including firmware; random access memory (RAM); magnetic disk storage media; optical storage media; flash memory devices; etc.), as well as electrical, optical, acoustical or other form of propagated signals (e.g., carrier waves, infrared signals, digital signals, etc.); etc.

In the foregoing specification, the invention has been described with reference to specific exemplary embodiments thereof. It will, however, be evident that various modifications and changes may be made thereto without departing from the broader spirit and scope of the invention as set forth in the appended claims. For example, the above described thermal management technique could also be applied to desktop computer device. The specification and drawings are, accordingly, to be regarded in an illustrative rather than a restrictive sense.

We claim:

1. An apparatus, comprising:
a self-focusing acoustic transducer; and
a heat generating component, wherein the self-focusing acoustic transducer is integrated within the heat generating component.

2. The apparatus of claim 1, wherein the self-focusing acoustic transducer comprises an array of self-focusing acoustic transducers integrated within the heat generating component.

3. The apparatus of claim 2, wherein the array of self-focusing acoustic transducers is formed over the hot-spots of the heat generating component.

4. The apparatus of claim 2, wherein the array of self-focusing acoustic transducers covers the backside of the heat generating component.

5. The apparatus of claim 1, wherein the heat generating component comprises a chipset within a mobile computing device.

6. The apparatus of claim 1, wherein the heat generating component comprises a heat spreader.

7. An apparatus, comprising:
a self-focusing acoustic transducer; and
an external wall of a computing device, the self-focusing acoustic transducer integrated into the external wall to remove heat from the external wall.

8. The apparatus of claim 7, wherein the self-focusing acoustic transducer has a length and a width of approximately 1 mm by 1 mm.

9. The apparatus of claim 7, wherein the self-focusing acoustic transducer is part of an array of self-focusing acoustic transducers.

10. A method of forming a self-focusing acoustic transducer, comprising:
forming a first electrode on a heat generating component of a computing device;
depositing a piezoelectric layer over the first electrode;
forming a second electrode on the piezoelectric layer;
depositing a low-stress material over the second electrode;
depositing a chamber material over the low-stress material; and
etching the chamber material to form a well within the chamber material above the first electrode and the second electrode.

11. The method of claim 10, wherein forming the first electrode comprises:
evaporating a metal layer onto the heat generating component; and
patterning the metal layer to form a plurality of progressively larger annular rings formed around one another.

12. The method of claim 10, wherein depositing a low-stress material over the second electrode comprises depositing silicon nitride.

13. The method of claim 10, wherein etching the semiconductor material to form the well within the semiconductor material above the first electrode and the second electrode comprises anisotropically etching the semiconductor material to form the well to have walls formed at an angle.

14. An computing device, comprising:
a heat generating component;
a self-focusing acoustic transducer fabricated by the method of forming a first electrode on a substrate of the computing device;
depositing a piezoelectric layer over the first electrode;
forming a second electrode on the piezoelectric layer;
depositing a low-stress material over the second electrode;
depositing a chamber material over the low-stress material; and
etching the chamber material to form a well within the chamber material above the first electrode and the second electrode; and
a battery to power the computing device.

15. The computing device of claim 14, wherein the substrate is a surface of the heat-generating component.

16. The computing device of claim 14, wherein the substrate is a surface of a heat spreader.

17. The computing device of claim 14, wherein the substrate is an external wall of a mobile computing device.

18. A computing device, comprising:
a self-focusing acoustic transducer integrated within a heat generating component of the computing device; and
a pair of electrodes of the self-focusing acoustic transducer formed on opposite sides of a piezoelectric material and a well formed above the pair of electrodes, the pair of electrodes to pulse a radio-frequency signal to create an acoustic wave within the well to push a fluid away from the heat generating component.

19. The computing device of claim 17, wherein the pair of electrodes is designed to pulse once the heat generating component has reached a temperature above a pre-determined threshold temperature.

20. The computing device of claim 17, wherein the pair of electrodes is designed to stop pulsing once the heat generating component has reached a temperature below a pre-determined threshold temperature.
